(19) United States
(12) Patent Application Publication
(10) Pub. No.: US 2015/0109705 A1
(43) Pub. Date: Apr. 23, 2015

(54) METHOD AND ASSOCIATED APPARATUS FOR PERFORMING ELECTROSTATIC DISCHARGE PROTECTION

(71) Applicants: Tzu-Heng Chang, Hsin-Chu City (TW); Fu-Yi Tsai, Hsin-Chu City (TW); Chia-Ku Tsai, Hsin-Chu City (TW)

(72) Inventors: Tzu-Heng Chang, Hsin-Chu City (TW); Fu-Yi Tsai, Hsin-Chu City (TW); Chia-Ku Tsai, Hsin-Chu City (TW)

(21) Appl. No.: 14/147,606

(22) Filed: Jan. 6, 2014

(30) Foreign Application Priority Data
Oct. 21, 2013 (TW) 102137937

(51) Int. Cl. H01L 27/02

(52) U.S. Cl. CPC H01L 27/0266
USPC 361/56

(57) ABSTRACT

A method for performing electrostatic discharge (ESD) protection and an associated apparatus are provided, where the method is applied to an electronic device, and the method includes: utilizing a trigger source formed with a plurality of Metal Oxide Semiconductor Field Effect Transistors (MOSFETs) to trigger a discharge operation, where the gate and the drain of any MOSFET within the plurality of MOSFETs are electrically connected to each other, causing the MOSFET to be utilized as a two-terminal component, and the MOSFETs that are respectively utilized as two-terminal components are connected in series; and utilizing an ESD apparatus to perform the discharge operation in response to the trigger of the trigger source, in order to perform ESD protection on the apparatus.

### BACKGROUND OF THE INVENTION

1. Field of the Invention

The present invention relates to electrostatic discharge (ESD), and more particularly, to a method for performing ESD protection and related apparatuses.

2. Description of the Prior Art

According to related arts, some new semiconductor manufacture processes are provided successively. However, some problems are generated correspondingly. For example, the thickness of the gate oxide may be reduced, making the chip easier to be damaged by the electrostatic discharge. For another example, in a specific semiconductor manufacture process, the oxide breakdown voltage may be very close to the junction breakdown voltage. Hence, traditional electrostatic discharge protection structures are very difficult to be put into practice. Therefore, a novel method is required to strengthen the electrostatic discharge protection structure without introducing undesired side effects, and more particularly, to make the electrostatic discharge protection structure have a lower trigger voltage and a lower holding voltage, to protect ultra-slim oxide layers in the advanced semiconductor technology.

### SUMMARY OF THE INVENTION

Hence, one objective of the present invention is to provide a method and an associated apparatus for performing electrostatic discharge protection to solve the aforementioned issue.

Another objective of the present invention is to provide a method and an associated apparatus for performing electrostatic discharge protection to improve the performance of the ESD protection and reduce the related production cost.

At least a preferred embodiment of the present invention provides a method for performing electrostatic discharge (ESD) protection and an associated apparatus are provided. The method is applied to an electronic device, and the method includes: utilizing a trigger source formed with a plurality of Metal Oxide Semiconductor Field Effect Transistors (MOSFETs) to trigger a discharge operation, wherein a gate and a drain of any MOSFET within the MOSFETs are electrically connected to each other, causing the MOSFET to be utilized as a two-terminal component, and the MOSFETs that are respectively utilized as two-terminal components are connected in series; and utilizing an ESD apparatus to perform the discharge operation in response to a trigger of the trigger source, in order to perform the ESD protection on the electronic device.

Besides providing the above method, the present invention also provides an apparatus for performing electrostatic discharge (ESD) protection. The apparatus includes at least a portion of an electronic device, and includes a trigger source and an ESD apparatus . The trigger source is formed with a plurality of Metal Oxide Semiconductor Field Effect Transistors (MOSFETs), arranged to trigger a discharge operation, wherein a gate and a drain of any MOSFET within the MOSFETs are electrically connected to each other, causing the MOSFET to be utilized as a two-terminal component, and the MOSFETs that are respectively utilized as two-terminal components are connected in series. The ESD apparatus is arranged to perform the discharge operation in response to a trigger of the trigger source, in order to perform the ESD protection on the electronic device.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating an apparatus for performing ESD protection according to a first embodiment of the present invention.

FIG. 2 is a diagram illustrating the arrangement of the apparatus shown in FIG. 1 within an electronic device according to an embodiment of the present invention.

FIG. 3 is a flowchart illustrating a method for performing ESD protection according to an embodiment of the present invention.

FIG. 4 is a diagram illustrating a control scheme involved with the method shown in FIG. 3 according to an embodiment of the present invention.

FIG. 5 is a diagram illustrating the arrangement of the apparatus shown in FIG. 4 within the electronic device according to an embodiment of the present invention.

FIG. 6 is a diagram illustrating a control scheme involved with the method shown in FIG. 3 according to another embodiment of the present invention.

FIG. 7 is a diagram illustrating a control scheme involved with the method shown in FIG. 3 according to another embodiment of the present invention.

FIG. 8 is a diagram illustrating a control scheme involved with the method shown in FIG. 3 according to another embodiment of the present invention.

### DETAILED DESCRIPTION

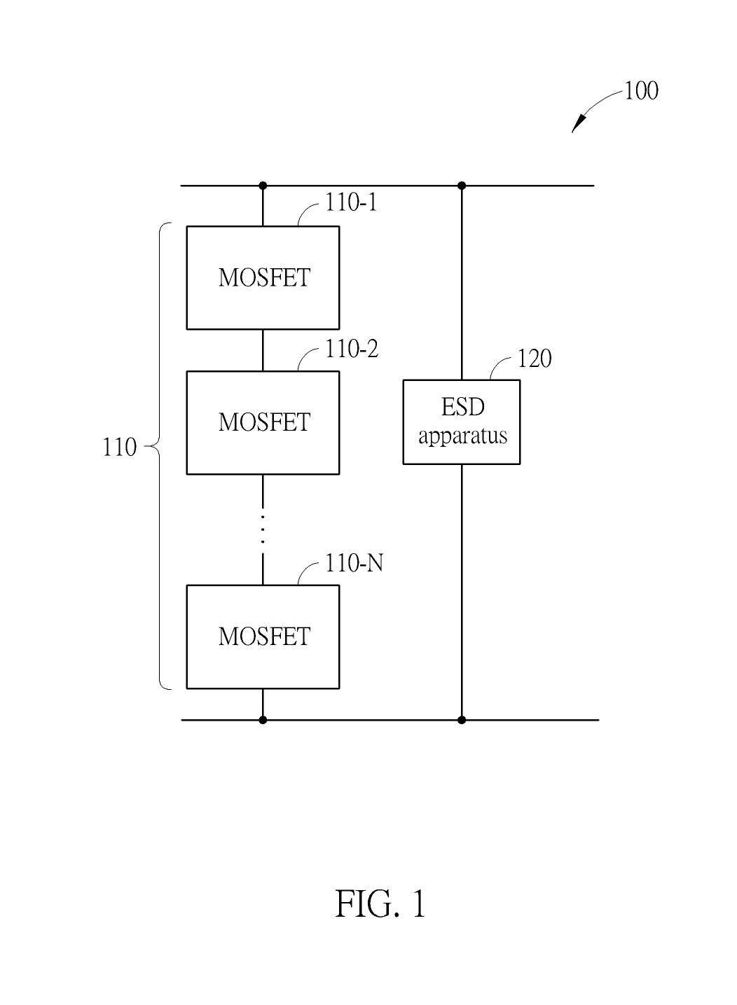

Please refer to FIG. 1, which is a diagram illustrating an apparatus for performing ESD protection according to a first embodiment of the present invention. The apparatus 100 includes at least a portion (e.g., part or all) of an electronic device. The apparatus 100 includes a trigger source 110 and an ESD apparatus 120 coupled to the trigger source 110. The trigger source 110 is formed with a plurality of Metal Oxide Semiconductor Field Effect Transistors (MOSFETs) 110-1, 110-2, . . . , 110-N. More particularly, the gate and the drain of any MOSFET 110-n within the plurality of MOSFETs 110-1, 110-2, . . . , 110-N are electrically connected to each other, causing the MOSFET 110-n to be utilized as a two-terminal component such as a diode, wherein the index n represents any integer within the range [1, N] . Hence, any MOSFET of the MOSFETs 110-1, 110-2, . . . , 110-N may be a diode-connected MOSFET. According to this embodiment, the trigger source 110 formed with the MOSFETs 110-1, 110-2, . . . , 110-N is used to trigger a discharging operation, and the ESD apparatus 120 is arranged to perform the discharge operation in response to the trigger of the trigger source 110, in order to perform ESD protection on the apparatus 100.

As shown in FIG. 1, the MOSFETs 110-1, 110-2, . . . , 110-N used as two-terminal elements are connected in series, while the ESD apparatus 120 and the trigger source 110 are connected in parallel. More particularly, two terminals of the ESD apparatus 120 are electrically connected to two specific terminals in the electronic device, respectively. Two terminals of the trigger source 110 are coupled to the two specific terminals in the electronic device, respectively. That is, two outmost terminals of the MOSFETs 110-1, 110-2, . . . , 110-N of the trigger source 110 are coupled to the two specific terminals in the electronic device, respectively. The aforementioned discharge operation includes discharging between the two specific terminals. For example, the two specific terminals may be any two terminals of a plurality of outer terminals of a package of a chip of the electronic device, such as an input terminal and a grounding terminal. However, this is merely for illustration, not a limitation to the present embodiment. According to a modification of this embodiment, the two specific terminals can be any two terminals of a plurality of outer terminals (respectively corresponding to the plurality of outer terminals of the package) of the chip of the electronic device. According to another modification of this embodiment, the two specific terminals can be any two terminals of a plurality of inner terminals of the chip of the electronic device. According to some modifications of this embodiment, as long as the implementation of the present invention is not affected, the two specific terminals can be any two terminals of a set formed with various terminals of the above-mentioned terminals of the electronic device (i.e., a set formed with the plurality of outer terminals of the package, the plurality of outer terminals of the chip, and the plurality of inner terminals of the chip).

In practical, the MOSFETs 110-1, 110-2, . . . , 110-N include at least one N-type Metal Oxide Semiconductor Field Effect Transistor (N-type MOSFET, abbreviated as NMOSFET hereinafter) and/or at least one P-type Metal Oxide Semiconductor Field Effect Transistor (P-type MOSFET, abbreviated as PMOSFET hereinafter). That is, the MOSFETs 110-1, 110-2, . . . , 110-N may include MOSFETs of the same type or MOSFETs of different types. For example, the MOSFETs 110-1, 110-2, . . . , 110-N may include at least one PMOPSFET, such as one PMOSFET or multiple PMOSFETs. For another example, the MOSFETs 110-1, 110-2, . . . , 110-N may include at least one NMOPSFET, such as one NMOSFET or multiple NMOSFETs. No matter whether the MOSFETs 110-1, 110-2, . . . , 110-N include MOSFETs of the same type or MOSFETs of different types, the gate and the drain of the MOSFET 110-n in the MOSFETs 110-1, 110-2, . . . , 110-N are electrically connected to each other. Each of the MOSFETs 110-1, 110-2, . . . , 110-N is a diode-connected MOSFET.

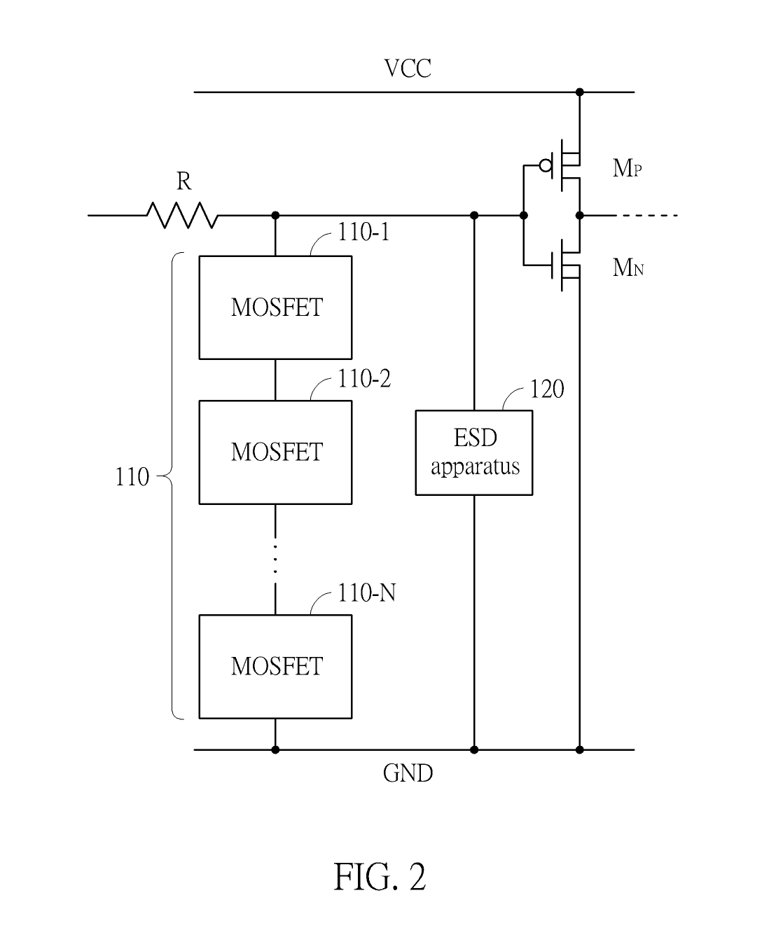

Please refer to FIG. 2, which is a diagram illustrating the arrangement of the apparatus 100 shown in FIG. 1 within an electronic device according to an embodiment of the present invention. For example, the aforementioned chip of the electronic device may include an input stage, and the input stage may include a resistor R and multiple MOSFETs such as a PMOSFET M_{P} and an NMOSFET M_{N}, wherein the resistor R is coupled to the input terminal of the aforementioned package. The power line VCC is coupled to a power terminal of the package, and the grounding line GND is coupled to the grounding terminal of the package.

In this embodiment, the two terminals of the ESD apparatus 120 can be coupled to the input terminal of the package and the grounding terminal of the package, respectively; besides, the two terminals of the trigger source 110 can be coupled to the input terminal of the package and the grounding terminal of the package, respectively. However, this is merely for illustration, not a limitation to the present embodiment. According to a modification of this embodiment, the two terminals of the ESD apparatus 120 may be coupled to the power terminal of the package and the grounding terminal of the package, respectively, and the two terminals of the trigger source 110 may be coupled to the power terminal of the package and the grounding terminal of the package, respectively. According to another modification of this embodiment, the two terminals of the ESD apparatus 120 can be coupled to the output terminal of the package and the grounding terminal of the package, respectively, and the two terminals of the trigger source 110 can be coupled to the output terminal of the package and the grounding terminal of the package, respectively. According to yet another modification of this embodiment, the two terminals of the ESD apparatus 120 can be coupled to the power terminal of the package and the output terminal of the package, respectively, and the two terminals of the trigger source 110 can be coupled to the power terminal of the package and the output terminal of the package, respectively. According to some modifications of this embodiment, as long as the implementation of the present invention is not affected, the two terminals of the ESD apparatus 120 can be coupled to any two selected terminals of the aforementioned set (i.e., the set formed with the plurality of outer terminals of the package, the plurality of outer terminals on the chip, and the plurality of inner terminals on the chip), and the two terminals of the trigger source 110 can be coupled to the two selected terminals of the set.

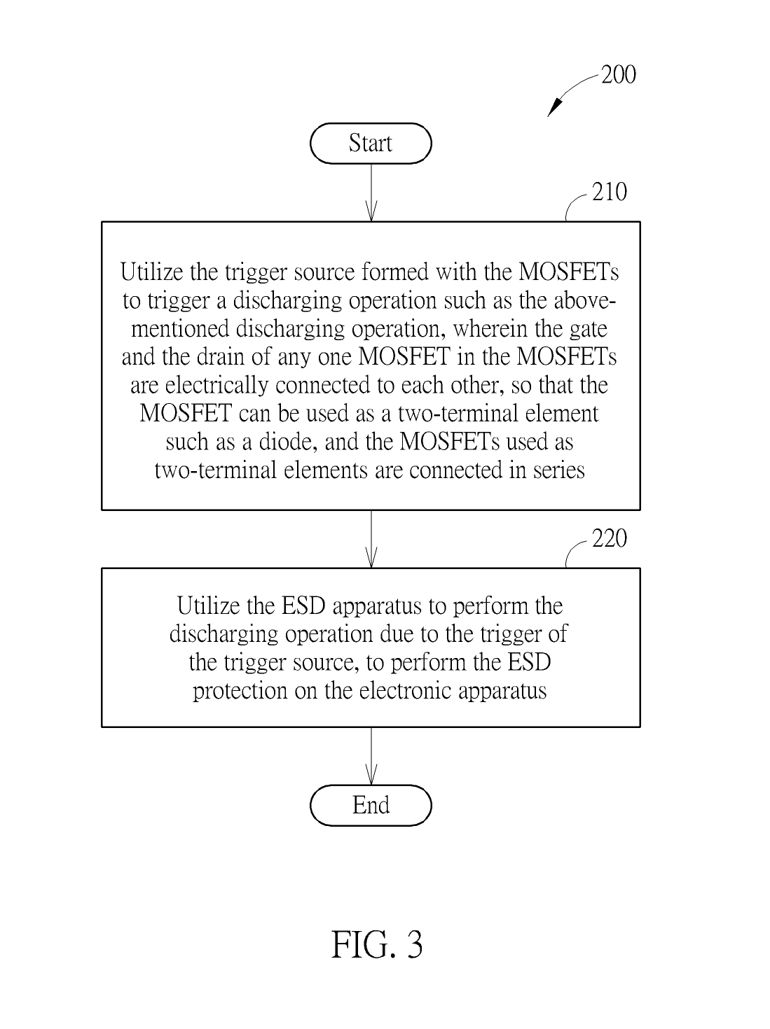

Please refer to FIG. 3, which is a flowchart illustrating a method for performing ESD protection according to an embodiment of the present invention. The method 200 can be applied to the apparatus 100 shown in FIG. 1, and more particularly, to the trigger source 110 and the ESD apparatus 120. The method 200 is described as follows.

In step 210, the trigger source 110 formed with the MOSFETs 110-1, 110-2, . . . , 110-N is utilized to trigger a discharging operation such as the above-mentioned discharging operation. The gate and the drain of any one MOSFET 110-n in the MOSFETs 110-1, 110-2, . . . , 110-N are electrically connected to each other, so that the MOSFET 110-n can be used as a two-terminal element such as a diode. Further, the MOSFETs 110-1, 110-2, . . . , 110-N used as two-terminal elements are connected in series.

In step 220, due to triggered by the trigger source 110, the ESD apparatus 120 is operative to perform the discharging operation mentioned in step 210, to perform the ESD protection on the electronic device. More particularly, the ESD apparatus 120 may include a MOSFET, a Silicon-Controlled Rectifier (SCR), a Field-Oxide Device (FOD), or a Bipolar Junction Transistor (BJT). For example, the ESD apparatus 120 can be a Silicon-Controlled Rectifier. For another example, the ESD apparatus 120 can be a Field-Oxide Device. For yet another example, the ESD apparatus 120 can be a Bipolar Junction Transistor.

Since each of the MOSFETs 110-1, 110-2, . . . , 110-N in the trigger source 110 has a fast response speed, the discharging operation can be triggered in time. Compared with the prior art design, the method and the related apparatus of the present invention can increase the response speed of the ESD protection. Hence, compared with the prior art design, the present invention provides a better ESD protection performance.

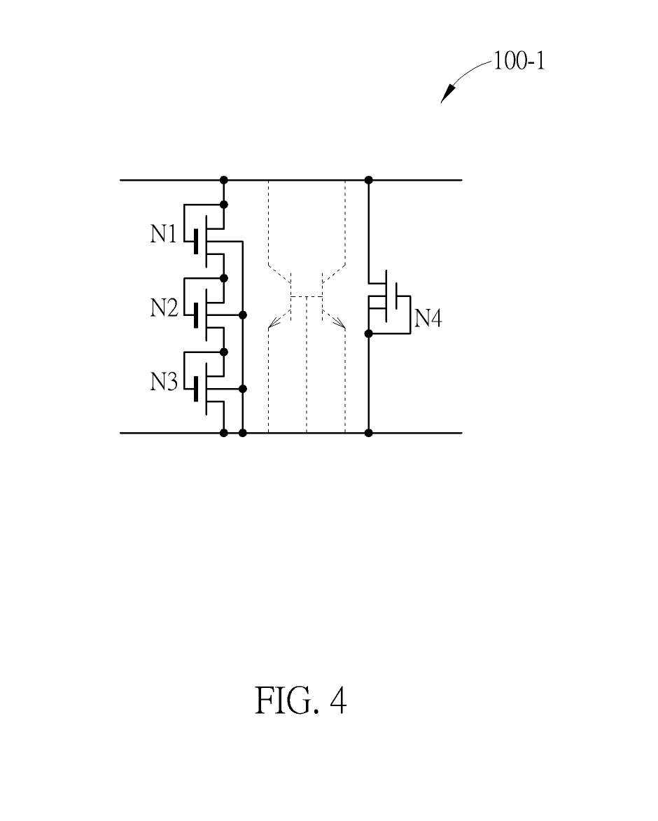

Please refer to FIG. 4, which is a diagram illustrating a control scheme involved with the method shown in FIG. 3 according to an embodiment of the present invention. The dotted lines in FIG. 4 show a parasitic BJT, not a substantial element. The apparatus 100-1 shown in FIG. 4 can be an example of the apparatus 100 shown in FIG. 1.

According to this embodiment, the number of the MOSFETs 110-1, 110-2, . . . , 110-N in the trigger source 110 can be 3. That is, the trigger source 110 includes three NMOSFETs N1, N2 and N3. Further, the ESD apparatus 120 includes an NMOSFET N4. However, this is merely for illustration, not a limitation to the present embodiment. According to some embodiments of this embodiment, the types of the MOSFETs 110-1, 110-2, . . . , 110-N in the trigger source 110 can be changed. For example, the NMOSFET N1 can be replaced with a first PMOSFET having a gate and a drain electrically connected to each other. For another example, the NMOSFET N2 can be replaced with a second PMOSFET having a gate and a drain electrically connected to each other. For another example, the NMOSFET N3 can be replaced with a third PMOSFET having a gate and a drain electrically connected to each other. For another example, the NMOSFET N1 can be replaced with the first PMOSFET, and the NMOSFET N2 can be replaced with the second PMOSFET. For another example, the NMOSFET N2 can be replaced with the second PMOSFET, and the NMOSFET N3 can be replaced with the third PMOSFET. For another example, the NMOSFET N3 can be replaced with the third PMOSFET, and the NMOSFET N1 can be replaced with the first PMOSFET. No matter whether the number N of MOSFETs 110-1, 110-2, . . . , 110-N in the trigger source 110 is changed or not, and no matter whether the MOSFET types of MOSFETs 110-1, 110-2, . . . , 110-N are changed or not, the thickness of the oxide layer of each of the MOSFETs 110-1, 110-2, . . . , 110-N in the trigger source 110 is larger than the thickness of the oxide layer of the MOSFET in the ESD apparatus 120. More particularly, each of the MOSFETs 110-1, 110-2, . . . , 110-N is implemented using a thick-oxide device to ensure a lower leakage current, and the MOSFET in the ESD apparatus 120 is implemented using a thin-oxide device to ensure a lower holding voltage.

As shown in FIG. 4, compared with the gate of the NMOSFET N4, the gate of each NMOSFET of the NMOSFETs N1, N2 and N3 is depicted using a bold line. This is because the thickness of the oxide layer of the gate of each NMOSFET in the NMOSFETs N1, N2 and N3 is larger than that of the oxide layer of the gate of the NMOSFET N4. Further, the ESD apparatus 120 includes the NMOSFET N4, and the gate and the source of the NMOSFET N4 are electrically connected to each other. However, this is merely for illustration, not a limitation to the present embodiment. According to some modifications of this embodiment, the types of the elements in the ESD apparatus 120 can be changed. The similar parts between the present and previous embodiments/modifications are omitted here for brevity.

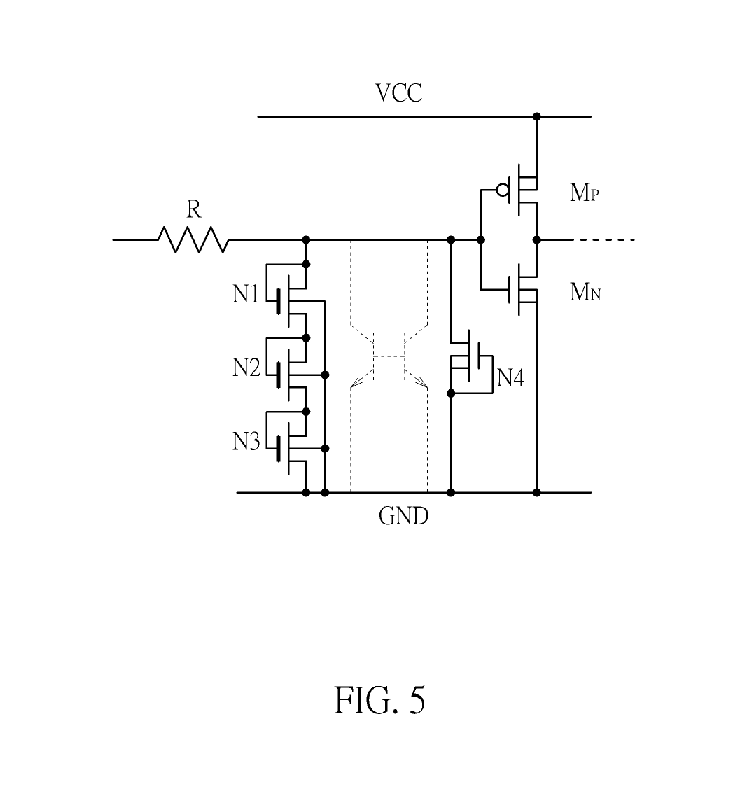

Please refer to FIG. 5, which is a diagram illustrating the arrangement of the apparatus 100-1 in FIG. 4 within the electronic device according to an embodiment of the present invention. The dotted lines in FIG. 5 show a parasitic BJT, not a substantial element.

According to this embodiment, the MOSFETs 110-1, 110-2, . . . , 110-N can generate a channel current in response to the electrical stress imposed upon the trigger source 110 to thereby trigger the discharging operation. That is, step 210 in this embodiment may further includes: utilizing the MOSFETs 110-1, 110-2, . . . , 110-N to generate a channel current in response to the electrical stress imposed upon the trigger source 110 to thereby trigger the discharging operation. Moreover, the ESD apparatus 120 includes a MOSFET such as the aforementioned NMOSFET N4 having a gate and a source electrically coupled to each other, wherein the channel current changes the substrate potential of this MOSDET (e.g., NMOSFET N4) of the ESD apparatus 120, such that a parasitic BJT of this MOSFET of the ESD apparatus 120 is turned on to perform the discharging operation.

Please note that, based on the arrangement in FIG. 5, the electrical stress is typically a positive-to-ground electrical stress. However, this is merely for illustration, not a limitation to the present embodiment. Further, the apparatus 100-1 in FIG. 4 may serve as a secondary ESD protection. Since the structure of the apparatus 100-1 is very neat, the required area of the chip will be very small. Hence, the apparatus 100-1 can be easily configured to be adjacent to inner elements (such as the resistor R and the NMOSFET M_{N}) of the electronic device.

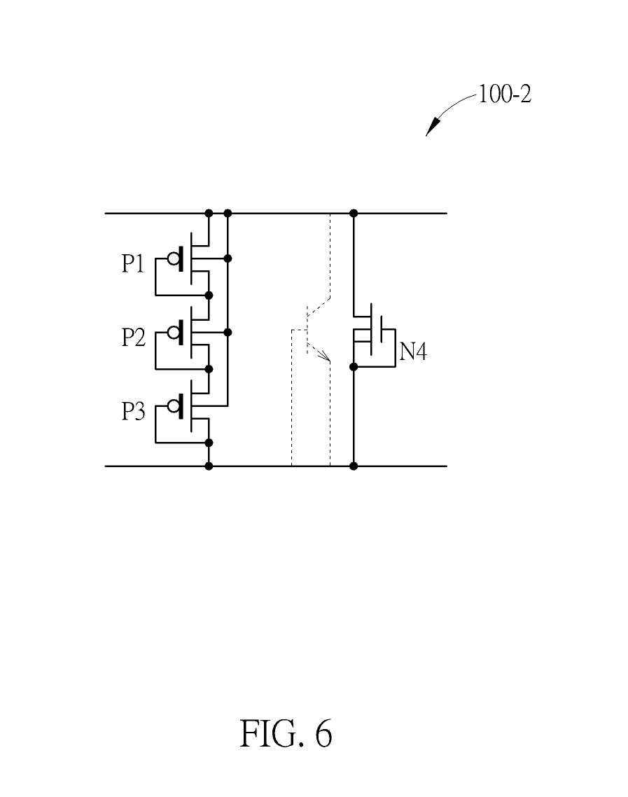

Please refer to FIG. 6, which is a diagram illustrating a control scheme involved with the method shown in FIG. 3 according to another embodiment of the present invention. The dotted lines in FIG. 6 show a parasitic BJT, not a substantial element. The apparatus 100-2 can be another example of the apparatus 100 shown in FIG. 1.

According to this embodiment, the number of the MOSFETs 110-1, 110-2, . . . , 110-N in the trigger source 110 can be 3. That is, the trigger source 110 includes three PMOSFETs P1, P2 and P3. Further, the ESD apparatus 120 includes an NMOSFET N4. However, this is merely for illustration, not a limitation to the present embodiment. According to some embodiments of this embodiment, the types of the MOSFETs 110-1, 110-2, . . . , 110-N in the trigger source 110 can be changed. For example, the PMOSFET P1 can be replaced with the NMOSFET N1 shown in FIG. 4. For another example, the PMOSFET P2 can be replaced with the NMOSFET N2 shown in FIG. 4. For another example, the PMOSFET P3 can be replaced with the NMOSFET N3 shown in FIG. 4. For another example, the PMOSFET P1 can be replaced with the NMOSFET N1 shown in FIG. 4, and the PMOSFET P2 can be replaced with the NMOSFET N2. For another example, the PMOSFET P2 can be replaced with the NMOSFET N2 shown in FIG. 4, and the PMOSFET P3 can be replaced with the NMOSFET N3. For another example, the PMOSFET 3 can be replaced with the NMOSFET N3 shown in FIG. 4, and the PMOSFET P1 can be replaced with the NMOSFET N1. No matter whether the number N of the MOSFETs 110-1, 110-2, . . . , 110-N in the trigger source 110 is changed or not, and no matter whether the MOSFET types of MOSFETs 110-1, 110-2, . . . , 110-N are changed or not, the thickness of the oxide layer of each MOSFET of the MOSFETs 110-1, 110-2, . . . , 110-N in the trigger source 110 is larger than the thickness of the oxide layer of the MOSFET in the ESD apparatus 120. More particularly, each of the MOSFETs 110-1, 110-2, . . . , 110-N is implemented using a thick-oxide device to ensure a lower leakage current, and the MOSFET in the ESD apparatus 120 is implemented using a thin-oxide device to ensure a lower holding voltage.

As shown in FIG. 6, compared with the gate of the NMOSFET N4, the gate of each PMOSFET of the PMOSFETs P1, P2 and P3 is depicted using a bold line. This is because the thickness of the oxide layer of the gate of each PMOSFET in the PMOSFETs P1, P2 and P3 is larger than that of the oxide layer of the gate of the NMOSFET N4. Further, the ESD apparatus 120 includes the NMOSFET N4, and the gate and the source of the NMOSFET N4 are electrically connected to each other. However, this is merely for illustration, not a limitation to the present embodiment. According to some modifications of this embodiment, the types of the elements in the ESD apparatus 120 can be changed. The similar parts between the present and previous embodiments/modifications are omitted here for brevity.

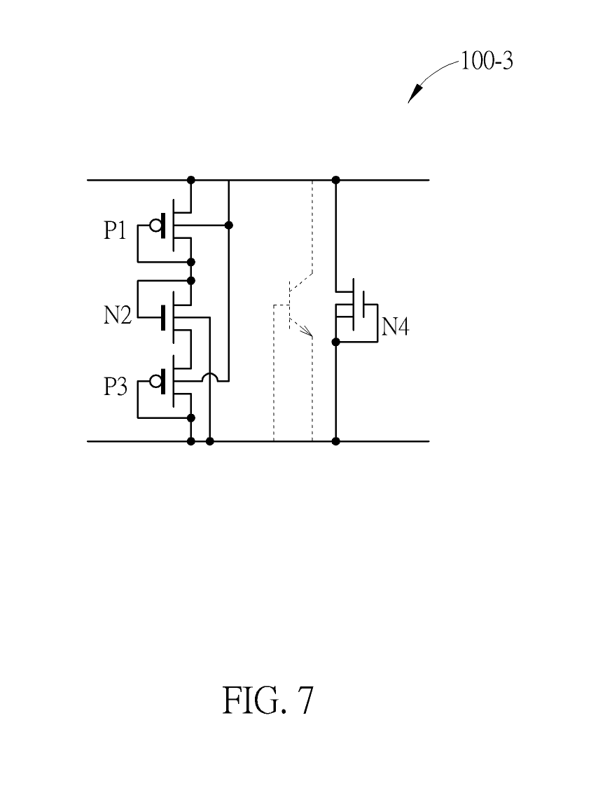

Please refer to FIG. 7, which is a diagram illustrating a control scheme involved with the method shown in FIG. 3 according to another embodiment of the present invention. The dotted lines in FIG. 7 show a parasitic BJT, not a substantial element. The apparatus 100-3 in FIG. 7 can be another example of the apparatus 100 in FIG. 1.

According to this embodiment, the number of the MOSFETs 110-1, 110-2, . . . , 110-N in the trigger source 110 can be 3. That is, the trigger source 110 includes two PMOSFETs P1, P3 and an NMOSFET N2. Further, the ESD apparatus 120 includes an NMOSFET N4. However, this is merely for illustration, not a limitation to the present embodiment. According to some embodiments of this embodiment, the types of the MOSFETs 110-1, 110-2, . . . , 110-N in the trigger source 110 can be changed. For example, the PMOSFET P1 can be replaced with the NMOSFET N1 shown in FIG. 4. For another example, the PMOSFET P3 can be replaced with the NMOSFET N3 shown in FIG. 4. No matter whether the number N of the MOSFETs 110-1, 110-2, . . . , 110-N in the trigger source 110 is changed or not, and no matter whether the MOSFET types of MOSFETs 110-1, 110-2, . . . , 110-N are changed or not, the thickness of the oxide layer of each MOSFET of the MOSFETs 110-1, 110-2, . . . , 110-N in the trigger source 110 is larger than that of the oxide layer of the MOSFET in the ESD apparatus 120. More particularly, each of the MOSFETs 110-1, 110-2, . . . , 110-N is implemented using a thick-oxide devices to ensure a lower leakage current, and the MOSFET in the ESD apparatus 120 is implemented using a thin-oxide device to ensure a lower holding voltage.

As shown in FIG. 7, compared with the gate of the NMOSFET N4, the gate of each of the PMOSFET P1, P3 and NMOSFET N2 is depicted using a bold line. This is because the thickness of the oxide layer of the gate of each of the PMOSFET P1, P3 and NMOSFET N2 is larger than that of the oxide layer of the gate of the NMOSFET N4. Further, the ESD apparatus 120 includes the NMOSFET N4, and the gate and the source of the NMOSFET N4 are electrically connected to each other. However, this is merely for illustration, not a limitation to the present embodiment. According to some modifications of this embodiment, the types of the elements in the ESD apparatus 120 can be changed. The similar parts between the present and previous embodiments/modifications are omitted here for brevity.

Please note that, based on any of the aforementioned embodiments/modifications, the discharging operation can be triggered in time due to the fact that the MOSFETs 110-1, 110-2, . . . , 110-N in the trigger source 110 can response rapidly. Compared with the prior art design, the method and the related apparatus of the present invention can increase the response speed of the ESD protection. Further, the trigger voltage of the trigger source 110 can be adjusted, and more particularly, be adjusted to relatively low to actually protect the inner elements of the chip fabricated using a new semiconductor manufacture process, wherein the number N of the MOSFETs 110-1, 110-2, . . . , 110-N can be determined according to the demands. Moreover, the channel current from the MOSFETs 110-1, 110-2, . . . , 110-N can slow down the voltage variation, and more particularly, slow down the overshooting voltage caused by the fast instant electrostatic discharge pulse, such as the electrostatic discharge pulse of the charged device model (CDM). Hence, compared with the prior art design, the present invention provides a better ESD protection performance.

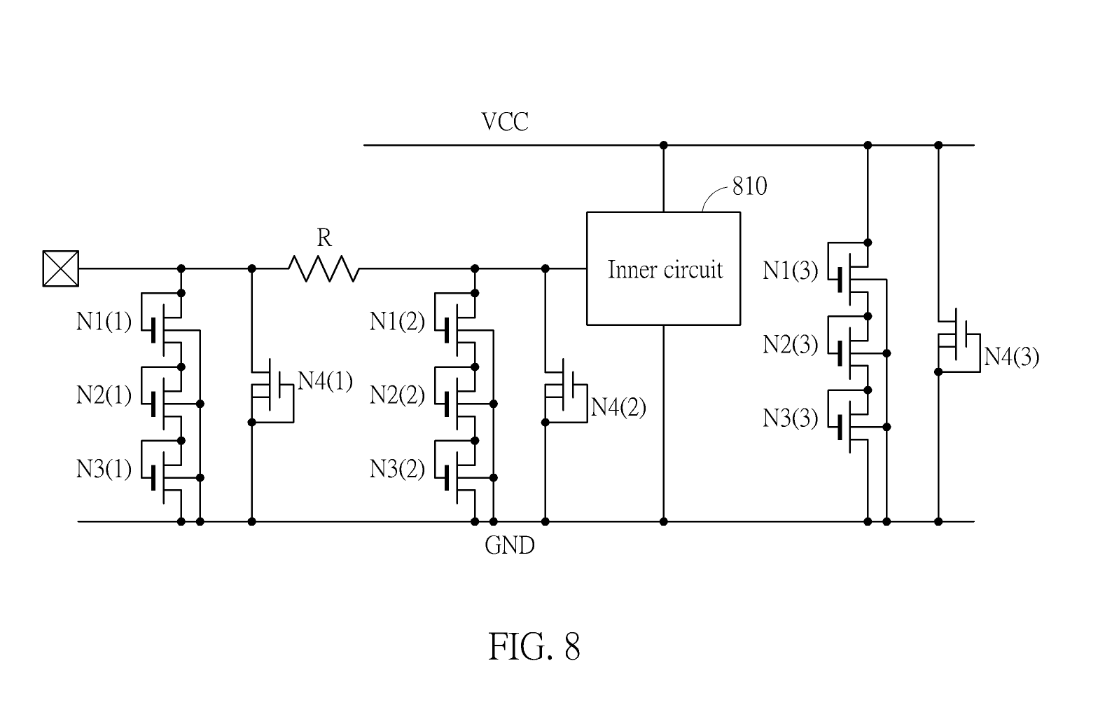

Please refer to FIG. 8, which is a diagram illustrating a control scheme involved with the method shown in FIG. 3 according to another embodiment of the present invention. The inner circuit 810 of the electronic device may include some inner elements of the electronic device (e.g., the aforementioned input stage including the NMOSFET M_{N} and the PMOSFET M_{P}; or an output stage of the aforementioned chip). The sets of the MOSFETs {{N1(1), N2(1), N3(1), N4(1)}, {N1(2), N2(2), N3(2), N4(2)}, {N1(3), N2(3), N3(3), N4(3)}} are replicas of the set of MOSFETs {N1, N2, N3, N4} shown in FIG. 4. According to this embodiment, the apparatus 100 as shown in FIG. 1 (as well as the apparatus 100-1 as shown in FIG. 4, the apparatus 100-2 as shown in FIG. 6, and the apparatus 100-3 as shown in FIG. 7) is suitable for performing ESD protection on various locations in the electronic device. The similar parts between the present and previous embodiments/modifications are omitted here for brevity.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for performing electrostatic discharge (ESD) protection, wherein the method is applied to an electronic device, the method comprising:
utilizing a trigger source formed with a plurality of Metal Oxide Semiconductor Field Effect Transistors (MOSFETs) to trigger a discharge operation, wherein a gate and a drain of any MOSFET within the MOSFETs are electrically connected to each other, causing the MOSFET to be utilized as a two-terminal component, and the MOSFETs that are respectively utilized as two-terminal components are connected in series; and
utilizing an ESD apparatus to perform the discharge operation in response to a trigger of the trigger source, in order to perform the ESD protection on the electronic device.

2. The method of claim 1, wherein the MOSFETs comprise at least one N-type Metal Oxide Semiconductor Field Effect Transistor (NMOSFET).

3. The method of claim 2, wherein the MOSFETs further comprise at least one P-type Metal Oxide Semiconductor Field Effect Transistor (PMOSFET).

4. The method of claim 1, wherein the MOSFETs comprise at least one P-type Metal Oxide Semiconductor Field Effect Transistor (PMOSFET).

5. The method of claim 1, wherein the ESD apparatus comprises a MOSFET, a Silicon-Controlled Rectifier (SCR), a Field-Oxide Device (FOD), or a Bipolar Junction Transistor (BJT).

6. The method of claim 1, wherein the ESD apparatus and the trigger source are connected in parallel.

7. The method of claim 6, wherein two terminals of the ESD apparatus are electrically connected to two specific terminals in the electronic device, respectively; two terminals of the trigger source are coupled to the two specific terminals in the electronic device, respectively; and the discharge operation comprises discharging between the two specific terminals.

8. The method of claim 1, wherein the ESD apparatus comprises a MOSFET having a gate and a source coupled to each other; and a thickness of an oxide layer of each of the MOSFETs is larger than a thickness of an oxide layer of the MOSFET in the ESD apparatus.

9. The method of claim 1, wherein the step of utilizing the trigger source formed with the MOSFETs to trigger the discharge operation comprises:
utilizing the MOSFETs to generate a channel current in response to an electrical stress imposed upon the trigger source, to trigger the discharge operation.

10. The method of claim 9, wherein the ESD apparatus comprises a MOSFET having a gate and a source coupled to each other; and the channel current changes a substrate potential of the MOSFET in the ESD apparatus such that a parasitic Bipolar Junction Transistor (BJT) of the MOSFET in the ESD apparatus is turned on to perform the discharging operation.

11. An apparatus for performing electrostatic discharge (ESD) protection, wherein the apparatus comprises at least a portion of an electronic device, and the apparatus comprising:
a trigger source formed with a plurality of Metal Oxide Semiconductor Field Effect Transistors (MOSFETs), arranged to trigger a discharge operation, wherein a gate and a drain of any MOSFET within the MOSFETs are electrically connected to each other, causing the MOSFET to be utilized as a two-terminal component, and the MOSFETs that are respectively utilized as two-terminal components are connected in series; and
an ESD apparatus, arranged to perform the discharge operation in response to a trigger of the trigger source, in order to perform the ESD protection on the electronic device.

12. The apparatus of claim 11, wherein the MOSFETs comprise at least one N-type Metal Oxide Semiconductor Field Effect Transistor (NMOSFET).

13. The apparatus of claim 12, wherein the MOSFETs further comprise at least one P-type Metal Oxide Semiconductor Field Effect Transistor (PMOSFET).

14. The apparatus of claim 11, wherein the MOSFETs comprise at least one P-type Metal Oxide Semiconductor Field Effect Transistor (PMOSFET).

15. The apparatus of claim 11, wherein the ESD apparatus comprises a MOSFET, a Silicon-Controlled Rectifier (SCR), a Field-Oxide Device (FOD), or a Bipolar Junction Transistor (BJT).

16. The apparatus of claim 11, wherein the ESD apparatus and the trigger source are connected in parallel.

17. The apparatus of claim 16, wherein the two terminals of the ESD apparatus are electrically connected to two specific terminals in the electronic device, respectively; two terminals of the trigger source are coupled to the two specific terminals in the electronic device, respectively; and the discharge operation comprises discharging between the two specific terminals.

18. The apparatus of claim 11, wherein the ESD apparatus comprises a MOSFET having a gate and a source coupled to each other; and a thickness of an oxide layer of each of the MOSFETs is larger than a thickness of an oxide layer of the MOSFET in the ESD apparatus.

19. The apparatus of claim 11, wherein the step of utilizing the trigger source formed with the MOSFETs to trigger the discharge operation comprises:
utilizing the MOSFETs to generate a channel current in response to an electrical stress imposed upon the trigger source, to trigger the discharge operation.

20. The apparatus of claim 19, wherein the ESD apparatus comprises a MOSFET having a gate and a source coupled to each other; and the channel current changes a substrate potential of the MOSFET in the ESD apparatus such that a parasitic Bipolar Junction Transistor (BJT) of the MOSFET in the ESD apparatus is turned on to perform the discharging operation.
